(19) United States
(12) Patent Application Publication
(10) Pub. No.: US 2016/0216298 A1
(43) Pub. Date: Jul. 28, 2016

(54) ELECTRICAL POWER MEASUREMENT SYSTEM AND METHOD

(71) Applicant: ECRTECH HOLDINGS PTY LTD, Brisbane, Queensland (AU)

(72) Inventors: Thomas Campeanu, Brisbane, Queensland (AU); Ron Campeanu, Brisbane, Queensland (AU)

(73) Assignee: ECRTECH HOLDINGS PTY LTD, Brisbane, Queensland (AU)

(21) Appl. No.: 14/913,824

(22) PCT Filed: Aug. 22, 2014
(86) PCT No.: PCT/AU2014/000831

§ 371 Date: Feb. 23, 2016

(30) Foreign Application Priority Data
Aug. 23, 2013 (AU) 2013903207

(51) Int. Cl. G01R 21/00; G01R 11/32; G01R 21/06

(52) U.S. Cl. CPC G01R 21/002; G01R 21/06; G01R 11/32

(57) ABSTRACT

A method of measuring electrical power including the steps of measuring a first electrical input variable at an input to a power conditioner connected to an electricity supply, measuring one or more electrical output variables at an output of the power conditioner, calculating a second electrical input variable at the input to the power conditioner according to the one or more electrical output variables measured at the output and the first electrical input variable measured at the input, calculating an estimated power according to the measured first electrical input variable and the calculated second electrical input variable, and sending the estimated power via a data interface.

### FIELD OF THE INVENTION

This invention relates generally to an electrical power measurement system and method and in particular to a system and method for calculating power savings.

### BACKGROUND TO THE INVENTION

Power conditioners have been developed that reduce a mains electricity supply voltage to a premises in order to reduce power consumption, and hence a cost of electricity. For example the mains electricity supply voltage may be reduced from 240 Vac to 220 Vac.

In order to determine power savings, it is necessary to measure power consumption with and without the power conditioner installed. However, this may involve interrupting the electricity supply to the premises which is inconvenient to users. In addition, electricity usage at a premises is generally not constant over time as different appliances, the weather, operational and behavioral variables may have a different effect on a level of power savings. Thus it is often difficult to estimate the power savings that can be achieved by a power conditioner.

The reference to any prior art in this specification is not, and should not be taken as, an acknowledgement or any form of suggestion that the prior art forms part of the common general knowledge in Australia or elsewhere.

### OBJECT OF THE INVENTION

It is an object, of some embodiments of the present invention, to provide consumers with improvements and advantages over the above described prior art, and/or overcome and alleviate one or more of the above described disadvantages of the prior art, and/or provide a useful commercial choice.

### SUMMARY OF THE INVENTION

In one form, although not necessarily the only or broadest form, the invention resides in a method of measuring electrical power including the steps of:

measuring a first electrical input variable at an input to a power conditioner connected to an electricity supply;

measuring one or more electrical output variables at an output of the power conditioner;

calculating a second electrical input variable at the input to the power conditioner according to the one or more electrical output variables measured at the output and the first electrical input variable measured at the input;

calculating an estimated power according to the measured first electrical input variable and the calculated second electrical input variable; and

sending the estimated power via a data interface.

Preferably, the first electrical input variable is an input voltage and the second electrical input variable is an estimated input current. Alternatively, the first electrical variable is an input current and the second electrical variable is an estimated input voltage.

Preferably, the one or more electrical output variables measured at the output includes one or more of an output voltage, an output current, and an actual power.

Preferably, the actual power is one or more of an apparent output power and a real output power. The estimated power may be an estimated apparent power and for an estimated real power.

Preferably, the method includes the step of calculating a power difference between the estimated power and the actual power, and sending the power difference via the data interface. Preferably, a level of power savings may be calculated from the power difference.

Preferably, the method includes the step of measuring an actual phase angle between the output voltage and the output current.

Preferably, the method includes the step of calculating the actual apparent power by multiplying an RMS output voltage by an RMS output current. Preferably, the method includes the step of calculating the actual real power by multiplying the actual apparent power by a power factor. Preferably, the power factor is a cosine of the actual phase angle measured between the output voltage and the output current.

Preferably, the method includes the step of calculating an estimated input current. In one embodiment, a ratio of the estimated input current and a measured input voltage equals a ratio of the measured output current and the measured output voltage. Thus an estimated RMS input current is calculated by dividing the RMS input voltage by the RMS output voltage and multiplying by the RMS output current.

Preferably, the method includes the step of calculating an estimated input phase angle. Preferably, a ratio of the estimated phase angle to the actual phase angle is equal to a ratio of the RMS input voltage to the RMS output voltage. Thus the estimated phase angle is equal to the measured phase angle multiplied by the RMS input voltage, and divided by the RMS output voltage.

Preferably, the method includes the step of calculating an estimated apparent power. The estimated apparent power may be calculated by multiplying the RMS input voltage by the estimated RMS input current.

Preferably, the method includes the step of calculating the estimated real power. The estimated real power may be calculated by multiplying the cosine of the estimated phase angle by the estimated apparent power.

Preferably, the method includes calculating an output voltage according to a desired level of savings set by a user, and setting the output voltage of the power conditioner according to the calculated output voltage.

Preferably, the method includes the step of calculating a power loss of the power conditioner. Preferably the power loss is an apparent power loss. Preferably, the power loss is a real power loss. Preferably, the real power loss is subtracted from the real power savings. Preferably, the apparent power loss is subtracted from the apparent power savings.

In another form, the invention resides in a measurement system, the measurement system including:

a processor and a memory coupled to the processor, the memory including computer readable program code components configured to cause the processor to:

measure a first electrical input variable at an input to a power conditioner connected to an electricity supply;

measure one or more electrical output variables at an output of the power conditioner;

calculate a second electrical input variable at the input to the power conditioner according to the one or more electrical output variables measured at the output and the first electrical input variable measured at the input;

calculate an estimated power according to the measured first electrical input variable and the calculated second electrical input variable; and

send the estimated power via a data interface.

In another form, the invention resides in a method of estimating a load power including the steps of:

measuring one or more electrical supply variables of an electricity supply;

calculating one or more electrical load variables based on the one or more measured electrical supply variables of the electricity supply, and an assumed load voltage, wherein the assumed load voltage is set by a user and is less than a voltage of the electricity supply;

calculating an estimated load power according to the calculated one or more electrical load variables and the assumed voltage; and

sending the estimated load power via a data interface.

Preferably, the one or more electrical supply variables include one or more of an electricity supply voltage, an electricity supply current and an electricity supply phase angle between the electricity supply voltage, and the electricity supply current.

Preferably, the method includes the step of calculating a supply power. The supply power may be one or more of an apparent supply power, a real supply power and a reactive supply power. The apparent supply power may be calculated by multiplying the electricity supply voltage by the electricity supply current.

Preferably, the method includes the step of calculating a real electricity supply power by multiplying the apparent electricity supply power by an electricity supply power factor. Preferably, the electricity supply power factor is a cosine of the phase angle measured between the electricity supply voltage and the electricity supply current.

Preferably, the one or more electrical load variables include an estimated load current. The estimated load current is calculated by multiplying the assumed load voltage by the electricity supply current and dividing by the measured electricity supply voltage.

Preferably, the method includes the step of calculating an estimated load power. The estimated load power may be one or more of an apparent estimated load power, a real estimated load power, and a reactive estimated load power.

Preferably, the apparent estimated load power is calculated by multiplying the assumed load voltage by the estimated load current.

The real estimated load power may be calculated by multiplying the apparent estimated load power by an estimated load power factor. The estimated load power factor may be calculated by taking the cosine of an estimated load phase angle. The estimated load phase angle may be calculated by dividing the measured electricity supply phase angle by the measured electricity supply voltage and multiplying by the assumed load voltage.

Preferably, the method includes the step of calculating a power difference between the estimated load power and the electricity supply power, and sending the power difference via the data interface.

### BRIEF DESCRIPTION OF THE DRAWINGS

An embodiment of the invention will be described with reference to the accompanying drawings in which:

FIG. 1 illustrates a block diagram of an electrical power measurement system according to an embodiment of the present invention; and

FIG. 2 illustrates a flow diagram of an electrical power measurement method according to an embodiment of the present invention.

### DETAILED DESCRIPTION OF THE PREFERRED EMBODIMENT

Elements of the invention are illustrated in concise outline form in the drawings, showing only those specific details that are necessary to understanding the embodiments of the present invention, but so as not to clutter the disclosure with excessive detail that will be obvious to those of ordinary skill in the art in light of the present description.

In this patent specification, adjectives such as first and second, left and right, front and back, top and bottom, etc., are used solely to define one element from another element without necessarily requiring a specific relative position or sequence that is described by the adjectives. Words such as “comprises” or “includes” are not used to define an exclusive set of elements or method steps. Rather, such words merely define a minimum set of elements or method steps included in a particular embodiment of the present invention. It will be appreciated that the invention may be implemented in a variety of ways, and that this description is given by way of example only.

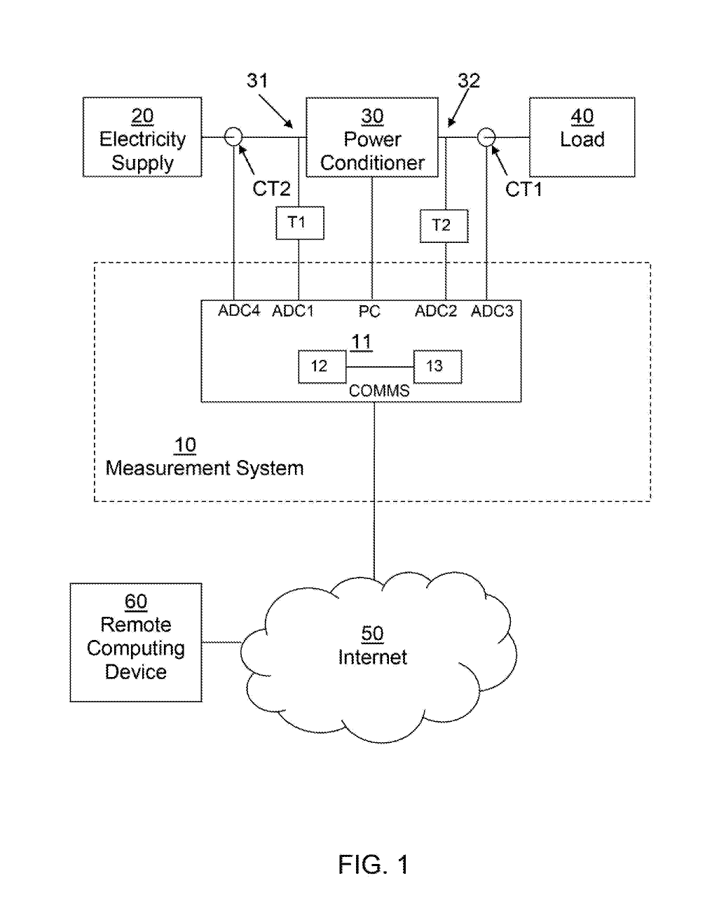

FIG. 1 illustrates a block diagram of an electrical power measurement system 10 according to an embodiment of the present invention. The measurement system 10 measures electrical variables at an input 31 to a power conditioner 30 from an electricity supply 20, and electrical variables at an output 32 of the power conditioner 30 that is connected to a load 40. From the measured electrical variables, the measurement system 10 calculates an actual power into the load 40 via the power conditioner 30. In addition the measurement system 10 calculates an estimated power that would be consumed if the load 40 were to be directly connected to the mains supply 10, rather than via the power conditioner 30. The system 10 then compares the estimated power to the actual power in order to estimate a level of power savings. The power savings may be estimated either in monetary terms or as a percentage.

The input 31 to the power conditioner 30 is connected to the electricity supply 20 via a suitable cable, or bus bars for example. Similarly the output 32 of the power conditioner 30 is connected to the load 40, for example, via a suitable cable or bus bars. The measurement system 10 connects to the input 31 and the output 32 in order to measure electrical variables.

The electricity supply 20 may be any suitable Alternating Current (AC) mains supply. The electricity supply 20 may be single phase or three phase. Some single phase voltages include 220 Vac, 230 Vac, 240 Vac, 100 Vac, 110 Vac, 115 Vac and 120 Vac. Three phase voltages may include 208 Vac, 220 Vac, 230 Vac, 440 Vac, 460 Vac and 480 Vac.

The power conditioner 30 reduces a voltage of the electricity supply 20 at the input 31 to a lower voltage at the output 32 to supply the load 40. For example, the power conditioner 30 may reduce the voltage of the electricity supply 20 from 230 Vac to 220 Vac. By lowering the voltage to the load 40, power consumption from the electricity supply 20 is generally reduced thus reducing a cost of electricity. In one embodiment, the power conditioner 40 is similar to the system described in Patent Co-operation Treaty publication no. WO2013/000034, titled “System and Method for Reducing Power Consumption in a Power Supply Circuit” by the present applicant, which is incorporated herein by reference.

The load 40 includes, for example, all appliances that are powered from a mains electricity supply in a residential or commercial premises via the power conditioner. For example the appliances may include fridges, freezers, televisions, lights, air conditioners, power tools, computer servers, industrial machines or any other appliance that may be connected to a lighting circuit or a power circuit.

In one embodiment, the measurement system 10 includes a microcontroller 11. The microcontroller 11 includes a plurality of Analogue to Digital Converter (ADC) ports, and may additionally include other interfaces such as a local area network port, a serial port, a parallel port, a Universal Serial Bus (USB) port, communications devices, wireless devices or any other suitable ports and interfaces.

In some embodiments, a first ADC port, ADC1 is connected to the input 31 of the power conditioner 30 via a transformer T1 in order to measure an input voltage at the input 31 to the power conditioner 30. A second ADC port, ADC2, is connected to the output 32 of the power conditioner 30 via a second transformer T2 in order to measure an output voltage at the output 32 of the power conditioner 30. The transformers T1, T2 reduce a voltage to a suitable level which is compatible with the ADC ports of the microcontroller 11. However it should be appreciated that any other suitable device may be used to reduce the voltage to a suitable level.

A third ADC port, ADC3, is connected to a first current transformer CT1 The first current transformer CT1 is attached around a live conductor connected to the output 32 of the power conditioner 30, in order to measure an output current. Similarly, a fourth ADC port, ADC4 is connected to a second current transformer CT2 attached around a live conductor connected to the input 31 of the power conditioner 30, in order to measure an input current. As will be understood by those having ordinary skill in the art, the current transformers CT1, CT2 may include biasing resistors and a voltage divider (not shown) so that an output of the first current transformer CT1 is at a suitable level at the third ADC port, ADC3, and the second current transformer CT2 is at a suitable level at a fourth ADC port, ADC4.

The microcontroller 11 includes a processor 12 connected to a memory 13. The memory 13 includes program code components configured to cause the processor 12 to perform the method of the present invention. The microcontroller 11 is configured to continuously measure electrical variables including the input voltage, the output voltage and the output current at an appropriate resolution, for example 0.5 ms for a 50 Hz electricity supply. In addition, by capturing waveforms, phase angles may also be measured in order to calculate apparent, real and reactive power, as would be understood by a person skilled in the art. Furthermore, the microcontroller 11 calculates other electrical variables from the measured electrical variables to determine the estimated power and the actual power. Alternatively, dedicated devices may be used to measure further electrical variables. For example a multimeter (not shown) interfaced to the microcontroller 11 may be used to measure Root Mean Squared (RM) voltages and RMS currents.

Although the input current, the output current, the input voltage, and the output voltage are measured using current transformers CT1, CT2, and transformers T1, T2 connected to the microcontroller 11, it should be appreciated that the current transformers CT1, CT2, and transformers T1, T2 connected to the microcontroller 11 may be replaced by approved metering units connected to the microcontroller 11. A first metering unit (not shown) may replace CT2 and T1, and a second metering unit (not shown) may replace CT1 and T2, to measure the input current, the output current, the input voltage, and the output voltage, as described below.

An actual apparent power into the load 40 is calculated by the microcontroller 11 as follows. The microcontroller calculates an RMS output voltage from the output voltage at the output 32 to the power conditioner 30. In addition, the microcontroller calculates an RMS output current from the output current at the output 32 of the power conditioner 30. The actual apparent power is calculated by multiplying the RMS output voltage by the RMS output current. Thus:

Actual apparent power=RMS output voltage×RMS output current Equation 1

An actual real power to the load 40 is calculated by multiplying the actual apparent power by an actual power factor. The actual power factor is determined by measuring a phase angle between the output voltage sinusoid and the output current sinusoid, and taking the cosine of the measured phase angle.

### Thus:

Actual real power=Actual apparent power×actual power factor Equation 2

Where:

Actual power tactor=cos (measured phase angle) Equation 3

Thus:

Actual real power=Actual apparent power×cos (measured phase angle) Equation 4

Once the actual real power and the actual apparent power into the load 40 have been calculated, the microcontroller 11 calculates an estimated real power and an estimated apparent power. The estimated real power and the estimated apparent power are estimations of electricity usage if the load 40 were directly connected to the electricity supply 20 rather than via the power conditioner 30.

From the measured input voltage, the microcontroller 11 determines an RMS input voltage, and estimates the RMS input current on the assumption that a ratio of the estimated RMS input current to the measured RMS input voltage is equal to a ratio of the RMS output current to the RMS output voltage. Thus:

$$estimated RMS input current = \frac{RMS input voltage}{RMS output voltage} \times RMS output current \qquad Equation 5$$

The estimated apparent power is calculated by multiplying the estimated RMS input current by the RMS input voltage:

estimated apparent power=estimated RMS input current×RMS input voltage Equation 6

Similarly, the estimated real power is calculated by multiplying the estimated apparent power by the cosine of the estimated phase angle. The estimated phase angle is calculated on the assumption that the ratio of the estimated phase angle to the actual phase angle is equal to the ratio of the RMS input voltage to the RMS output voltage. The estimated phase angle at the electricity supply is calculated by the microcontroller 11 using the equation:

$$Equation 7$$

$$\begin{matrix}estimated phase angle = actual phase angle \times \frac{RMS input voltage}{RMS output voltage} \\ = {cos}^{- 1} ( actual power factor ) \times Equation 8 \\ \frac{RMS input voltage}{RMS output voltage}\end{matrix}$$

### Also:

estimated real power=estimated apparent power×cos (est. phase angle) Equation 9

Where est.=estimated

Once the actual real power and the actual apparent power into the load 40, and the estimated real power and the estimated apparent power, have been calculated, power savings may be calculated. Power savings are calculated by the microcontroller 11 as the ratio of the real power to the estimated real power, and the ratio of the estimated apparent power to the apparent power. Thus:

$$\begin{matrix}\% real power savings = \frac{( estimated real power - actual real power )}{estimated real power} \times 100 & Equation 10 \\ \% apparent power savings = \frac{( est . app . power - actual app . power )}{estimated apparent power} \times 100 & Equation 11\end{matrix}$$

It should be appreciated that any one or more of the actual real power, the actual apparent power, the estimated real power, the estimated apparent power and the real and apparent power savings may be sent to a user via a data interface. Such data interfaces may include a communication interface, a printer, a display, an interface to a software program, or any other suitable data interface.

Furthermore, from the above measurements and calculations, the microcontroller may calculate an actual reactive power at the output of the power conditioner 30, and an estimated reactive power:

actual reactive power=actual apparent power×sin (actual phase angle)

estimated reactive power=est. apparent power×sin (est. phase angle)

Tables 1-8 show measurements and results for a number of devices connected to the output 32 of the power conditioner 30 in order to demonstrate power savings calculated according to the present invention.

Table 1 below shows actual measurements for a fridge and an oil heater connected to the output 32 of the power conditioner 30.

TABLE 1

| Electrical variable | Measurement |
|---|---|
| RMS output current (Amps) | 5.0924 |
| RMS output voltage (Volts) | 216.7 |
| Measured phase angle at output (degrees) | 10.4 |
| RMS input voltage (Volts) | 231.4 |

Thus using equations 1-11 above, the power savings are calculated as shown below in table 2.

TABLE 2

| Parameter | Result |
|---|---|
| Actual apparent power from Eq. 1 = | 1103.5231 |
| Actual real power from Eq. 2 = | 1085.3938 |
| Actual power factor from Eq.3 = | 0.9836 |
| Or actual real power from Eq. 4 = | 1085.3938 |
| Estimated RMS input current from Eq. 5 = | 5.4378 |
| Estimated apparent power from Eq. 6 = | 1258.3177 |
| Estimated phase angle from Eq. 7 = | 11.1055 |
| Or estimated phase angle from Eq. 8 = | 11.1055 |
| Estimated real power from Eq. 9 = | 1234.7547 |
| % real power savings from Eq. 10 = | 12.0964 |
| % apparent power savings from Eq. 11 = | 12.3017 |

Table 3 shows measurements for load consisting of the oil heater alone.

TABLE 3

| Electrical variable | Measurement |
|---|---|
| RMS output current (Amps) | 3.9760 |
| RMS output voltage (Volts) | 216.5 |
| Measured phase angle at output (degrees) | 2.56 |
| RMS input voltage (Volts) | 232.1 |

Similarly using equations 1-11 above the power savings are calculated as shown below in table 4.

TABLE 4

| Parameter | Result |
|---|---|
| Actual apparent power from Eq. 1 = | 860.8040 |
| Actual real power from Eq. 2 = | 859.9449 |
| Actual power factor from Eq. 3 = | 0.9990 |
| Or actual real power from Eq. 4 = | 859.9449 |
| Estimated RMS input current from Eq. 5 = | 4.2625 |
| Estimated apparent power from Eq. 6 = | 989.3245 |
| Estimated phase angle from Eq. 7 = | 2.7445 |
| Or estimated phase angle from Eq. 8 = | 2.7445 |
| Estimated real power from Eq. 9 = | 988.1897 |
| % real power savings from Eq. 10 = | 12.9778 |
| % apparent power savings from Eq. 11 = | 12.9907 |

In another example, table 5 shows measurements for a load consisting of a vacuum cleaner.

TABLE 5

| Electrical variable | Measurement |
|---|---|
| RMS output current (Amps) | 3.2636 |
| RMS output voltage (Volts) | 216.5 |
| Measured phase angle at output (degrees) | 17.86 |
| RMS input voltage (Volts) | 233.8 |

Similarly using equations 1-11 above the power savings are calculated as shown below in table 6.

TABLE 6

| Parameter | Result |
|---|---|
| Actual apparent power from Eq. 1 = | 706.5694 |
| Actual real power from Eq. 2 = | 672.5189 |
| Actual power factor from Eq. 3 = | 0.9518 |
| Or actual real power from Eq. 4 = | 672.5189 |
| Estimated RMS input current from Eq. 5 = | 3.5244 |
| Estimated apparent power from Eq. 6 = | 824.0016 |
| Estimated phase angle from Eq. 7 = | 19.2872 |
| Or estimated phase angle from Eq. 8 = | 19.2872 |
| Estimated real power from Eq. 9 = | 777.7545 |
| % real power savings from Eq. 10 = | 13.5307 |
| % apparent power savings from Eq. 11 = | 14.2514 |

In another example, table 7 shows measurements for a load consisting of a vacuum cleaner and a fridge.

TABLE 7

| Electrical variable | Measurement |
|---|---|
| RMS output current (Amps) | 4.4056 |
| RMS output voltage (Volts) | 217.8 |
| Measured phase angle at output (degrees) | 25.89 |
| RMS input voltage (Volts) | 233.1 |

Similarly using equations 1-11 above the power savings are calculated as shown below in table 8.

TABLE 8

| Parameter | Result |
|---|---|
| Actual apparent power from Eq. 1 = | 959.5397 |
| Actual real power from Eq. 2 = | 863.2345 |
| Actual power factor from Eq. 3 = | 0.8996 |
| Or actual real power from Eq. 4 = | 863.2345 |
| Estimated RMS input current from Eq. 5 = | 4.7151 |
| Estimated apparent power from Eq. 6 = | 1099.0861 |
| Estimated phase angle from Eq. 7 = | 27.7087 |
| Or estimated phase angle from Eq. 8 = | 27.7087 |
| Estimated real power from Eq. 9 = | 973.0461 |
| % real power savings from Eq. 10 = | 11.2853 |
| % apparent power savings from Eq. 11 = | 12.6966 |

Tables 9 and 10 show measurements and results to an industrial load, in order to demonstrate power savings. The measurement shown below in table 9 is a single phase at an instant in time, i.e. one cycle of the mains frequency. However it should be appreciated that similar measurements may be made on each phase of the mains, and continuously over time.

TABLE 9

| Electrical variable | Measurement |
|---|---|
| RMS output current (Amps) | 186.74 |
| RMS output voltage (Volts) | 222.00 |
| Measured phase angle at output (degrees) | 16.2397 |
| RMS input voltage (Volts) | 246.44 |

TABLE 10

| Parameter | Result |
|---|---|
| Actual apparent power from Eq. 1 = | 41456.2800 |
| Actual real power from Eq. 2 = | 39802.1744 |
| Actual power factor from Eq. 3 = | 0.9601 |
| Or actual real power from Eq. 4 = | 39802.1744 |
| Estimated RMS input current from Eq. 5 = | 207.2982 |
| Estimated apparent power from Eq. 6 = | 51086.5742 |
| Estimated phase angle from Eq. 7 = | 18.0276 |
| Or estimated phase angle from Eq. 8 = | 18.0276 |
| Estimated real power from Eq. 9 = | 48578.6194 |
| % real power savings from Eq. 10 = | 18.0665 |
| % apparent power savings from Eq. 11 = | 18.8509 |

As previously mentioned, the second current transformer CT2 may be used to measure current at the input 31 to the power conditioner 30. The measurements may be used to verify the accuracy of the estimated current and the estimated power at the input 31 of power conditioner 30. From measurements performed by the Applicant, the estimated results substantially correlate with the measured results.

As previously mentioned the power measurement system of the present invention may be used to measure power savings of a multi phase electricity supply. In this case, the electrical parameters are measured on each phase of electricity supply at the input and the output of the power conditioner. The savings may be calculated per phase, or combined to calculate a combined power saving.

In another embodiment of the present invention, calculations may be made to estimate a load power based on an assumed voltage to the load, in order to demonstrate power savings without installing the power conditioner 30, or to provide a verification of the results obtained above using equations 1-11. In this case the electricity supply is connected directly to the load 40, rather than through the power conditioner 30.

In this embodiment, one or more electrical supply variables are measured at the electricity supply. For example, an electricity supply voltage, an electricity supply current and an electricity supply phase angle between the electricity supply voltage and the electricity supply current are measured. The electrical supply variables may be measured using the apparatus shown in FIG. 1.

Using the measured electricity supply variables, an apparent supply power and a real supply power may be calculated, as shown below:

Apparent electricity supply power=electricity supply voltage×electricity supply current Equation 12

Real electricity supply power=Apparent electricity supply power×electricity supply power factor Equation 13

where: electricity supply power factor=cos (electricity supply phase angle) Equation 14

Thus:

Real electricity supply power=Apparent electricity supply power×cos (electricity supply phase angle) Equation 15

An estimated load current is calculated on the assumption that the ratio of the estimated load current to the electricity supply current is equal to the ratio of the assumed load voltage to the electricity supply voltage. Thus the estimated load current is calculated by multiplying the assumed load voltage by the electricity supply current and dividing by the measured electricity supply voltage.

$$estimated load current = \frac{assumed load voltage}{electricity supply voltage} \times electricity supply current \qquad Equation 16$$

Thus the estimated apparent load power may be calculated by multiplying the estimated load current by the assumed load voltage:

apparent estimated load power=assumed load voltage×estimated load current Equation 17

In order to calculate the real estimated load power, an estimated load phase angle must first be calculated on the assumption that the ratio of the estimated load phase angle to the electricity supply phase angle is equal to the ratio of the assumed load voltage to the electricity supply voltage. Thus:

$$est . load phase angle = \frac{assumed load voltage}{electricity supply voltage} \times electricity supply phase angle \qquad Equation 18$$

Once the estimated load phase angle has been calculated, the real estimated load power is calculated by multiplying the cosine of the estimated phase angle (i.e. the estimated power factor of the load) and multiplying by the apparent estimated load power:

real est. load power=cos (est. load phase angle)×apparent est. load power Equation 19

Once the apparent electricity supply power, the real electricity supply power, the apparent estimated load power and the real estimated load power have been calculated, power savings may also be calculated.

$$\begin{matrix}\% App . power savings = \frac{( \begin{matrix}app . electricity supply power - \\ app . est . load power\end{matrix} )}{app . electricity supply power} \times 100 & Equation 20 \\ \% Real power savings = \frac{( \begin{matrix}real electricity supply power - \\ real est . load power\end{matrix} )}{real electricity supply power} \times 100 & Equation 21\end{matrix}$$

Tables 11-18 below show measurements taken at an electricity supply when connected to various loads, and results of power savings using equations 12-21 above.

Tables 11 and 12 show measurements and results respectively for a load consisting of a fridge and an oil heater, in order to demonstrate power savings using an assumed voltage according to an embodiment of the present invention.

TABLE 11

| Electrical variable | Measurement |
|---|---|
| Electricity supply current (RMS Amps) | 5.2816 |
| Electricity supply voltage (RMS Volts) | 231.4 |
| Electricity supply phase angle at input (degrees) | 11.44 |
| Assumed voltage (RMS Volts) | 220.0 |

TABLE 12

| Parameter | Result |
|---|---|
| Apparent electricity supply power from Eq. 12 = | 1222.1622 |
| Real electricity supply power from Eq. 13 = | 1197.8815 |
| Electricity supply power factor from Eq. 14 = | 0.9801 |
| Real electricity supply power from Eq. 15 = | 1197.8815 |
| Estimated load current from Eq. 16 = | 5.0214 |
| Apparent estimated load power from Eq. 17 = | 1104.7080 |
| Est. load phase angle from Eq. 18 = | 10.8764 |
| Estimated real power from Eq. 19 = | 1084.8636 |
| % real power savings from Eq. 20 = | 9.4348 |
| % apparent power savings from Eq. 21 = | 9.6104 |

Tables 13 and 14 show measurements and results respectively for a load consisting of an oil heater, in order to demonstrate power savings using an assumed voltage.

TABLE 13

| Electrical variable | Measurement |
|---|---|
| Electricity supply current (RMS Amps) | 4.2492 |
| Electricity supply voltage (RMS Volts) | 232.1 |
| Electricity supply phase angle at input (degrees) | 2.56 |
| Assumed voltage (RMS Volts) | 220.0 |

TABLE 14

| Parameter | Result |
|---|---|
| Apparent electricity supply power from Eq. 12 = | 986.2393 |
| Real electricity supply power from Eq. 13 = | 985.2550 |
| Electricity supply power factor from Eq. 14 = | 0.9990 |
| Real electricity supply power from Eq. 15 = | 985.2550 |
| Estimated load current from Eq. 16 = | 4.0277 |
| Apparent estimated load power from Eq. 17 = | 886.0891 |
| Est. load phase angle from Eq. 18 = | 2.4265 |
| Estimated real power from Eq. 19 = | 885.2946 |
| % real power savings from Eq. 20 = | 10.1456 |
| % apparent power savings from Eq. 21 = | 10.1548 |

Tables 15 and 16 show measurements and results respectively for a load consisting of a vacuum cleaner, in order to demonstrate power savings using an assumed voltage.

TABLE 15

| Electrical variable | Measurement |
|---|---|
| Electricity supply current (RMS Amps) | 3.4768 |
| Electricity supply voltage (RMS Volts) | 233.8 |
| Electricity supply phase angle at input (degrees) | 18.27 |
| Assumed voltage (RMS Volts) | 220.0 |

TABLE 16

| Parameter | Result |
|---|---|
| Apparent electricity supply power from Eq. 12 = | 812.8758 |
| Real electricity supply power from Eq. 13 = | 771.8986 |
| Electricity supply power factor from Eq. 14 = | 0.9496 |
| Real electricity supply power from Eq. 15 = | 771.8986 |
| Estimated load current from Eq. 16 = | 3.2716 |
| Apparent estimated load power from Eq. 17 = | 719.7482 |
| Est. load phase angle from Eq. 18 = | 17.1916 |
| Estimated real power from Eq. 19 = | 687.5910 |
| % real power savings from Eq. 20 = | 10.9221 |
| % apparent power savings from Eq. 21 = | 11.4566 |

Tables 17 and 18 show measurements and results to a load consisting of a vacuum cleaner and a fridge, in order to demonstrate power savings.

TABLE 17

| Electrical variable | Measurement |
|---|---|
| Electricity supply current (RMS Amps) | 4.7296 |
| Electricity supply voltage (RMS Volts) | 233.1 |
| Electricity supply phase angle at input (degrees) | 11.44 |
| Assumed voltage (RMS Volts) | 220.0 |

TABLE 18

| Parameter | Result |
|---|---|
| Apparent electricity supply power from Eq. 12 = | 1102.4698 |
| Real electricity supply power from Eq. 13 = | 1080.5669 |
| Electricity supply power factor from Eq. 14 = | 0.9801 |
| Real electricity supply power from Eq. 15 = | 1080.5669 |
| Estimated load current from Eq. 16 = | 4.4638 |
| Apparent estimated load power from Eq. 17 = | 982.0362 |
| Est. load phase angle from Eq. 18 = | 10.7971 |
| Estimated real power from Eq. 19 = | 964.6510 |
| % real power savings from Eq. 20 = | 10.7273 |
| % apparent power savings from Eq. 21 = | 10.9240 |

Although tables 1-18 using equations 1-21 show measurements and results taken at an instant in time over a single cycle of the mains, it should be appreciated that the microcontroller 11 may continuously take measurements and record power savings over a period of time. The recorded measurements and results may then be displayed graphically to a user, or displayed in any other suitable manner such as in a tabular format.

As previously mentioned, the microcontroller 11 of the measurement system 10 may include a communications port COMM. Such a communications port COMM may access the Internet 50 so that users can access the measurement system 10 from a remote computer 60. In addition, users via the remote computer 60 may configure the power conditioner 30. For example, the user may configure the output voltage of the power conditioner 30, such as to increase the output voltage from 220 Vac to 225 Vac. In addition, the user may view historical power savings in any suitable format, such as graphically.

In another embodiment, the measurement system 10 may be incorporated in the power conditioner 30. Alternatively, the power conditioner 30 may be configured to take electrical variable measurements and pass the measurements to the measurement system 10 via port PC, which are then analysed by the microcontroller 11 as described above.

As would be understood by a person skilled in the art, the power conditioner 30 may introduce a power loss between the input 31 and the output 32. The loss may be calculated according to the following equations, in order to correct the estimated savings. The loss is calculated by also measuring the current at the input 31 to the power conditioner 30.

Thus:

$$\% apparent power loss = \frac{actual input power - actual output power}{actual input power} \times 100 \qquad Equation 22$$

where:

actual input power=input voltage×input current

actual output power=output voltage×output current

and;

$$\% real power loss = \frac{real input power - real outut power )}{real input power} \times 100 \qquad Equation 23$$

where:

$$\begin{matrix}real input power = actual input power \times measured output power factor \\ = actual input power \times cos \\ ( measured output phase angle )\end{matrix}$$

$$\begin{matrix}real output power = actual output power \times measured output power factor \\ = actual output power \times cos \\ ( measured phase angle )\end{matrix}$$

From Equations 22 and 23, the savings calculated according to equations 10, 11, 20 and 21 may be corrected. Thus the result of equation 22 is subtracted from Equation 11 and Equation 20, and the result of Equation 23 is subtracted from Equation 10 and Equation 21, and the % corrected power savings are:

% corrected apparent power savings=% apparent power savings−% apparent power loss Equation 24

and;

% corrected real power savings=% real power savings−% real power loss Equation 25

In yet another embodiment, a desired level of savings may be set by a user, and the microcontroller 11 may calculate an output voltage at the output 32 of the power conditioner 30 in order to achieve the desired level of savings. Once calculated, the microcontroller 11 communicates with the power conditioner 30 to set the output voltage with the calculated output voltage. However it should be appreciated that constraints may be set in order to check that the output voltage is not set too low or too high that may cause damage to appliances connected to the load 40.

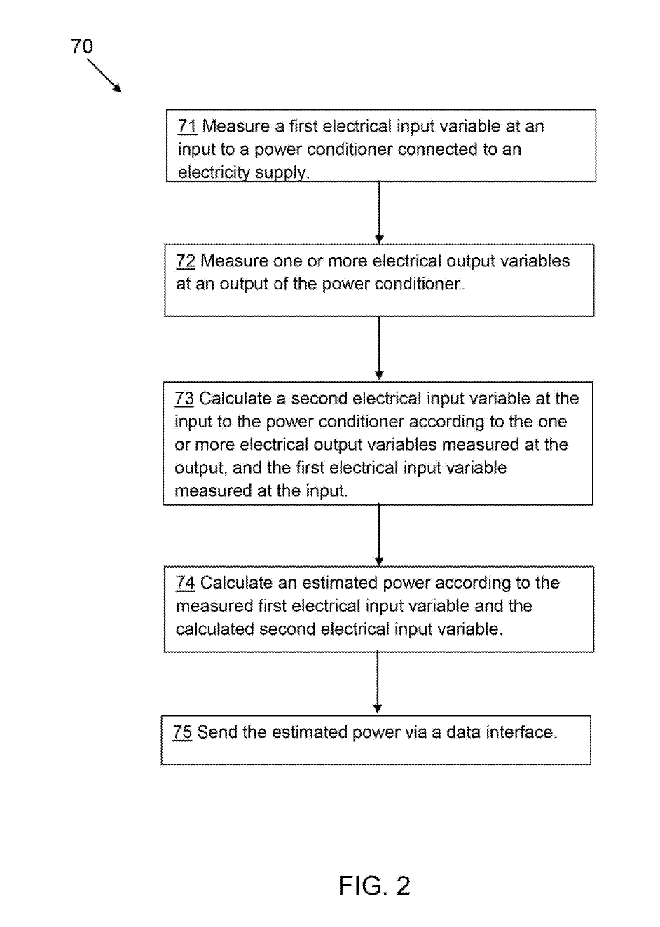

The invention can be summarised with reference to FIG. 2. FIG. 2 illustrates a flow diagram 70 of a power measurement method according to an embodiment of the present invention. At step 71 a first electrical input variable is measured at an input 31 to a power conditioner 30 connected to an electricity supply 20. At step 72 one or more electrical output variables are measured at an output 32 of the power conditioner 30. At step 73, a second electrical input variable at the input 31 to the power conditioner 30 is calculated according to the one or more electrical output variables measured at the output 32 and the first electrical input variable measured at the input 31. At step 74, an estimated power is calculated according to the measured first electrical input variable and the calculated second electrical input variable. At step 75 the estimated power is sent via a data interface. In addition, an actual power may be calculated at the output 32 of the power conditioner 30 and compared with the estimated power in order to determine power savings. The estimated power and the power savings may also be sent via the data interface.

In summary, a power measurement system, according to some embodiments, includes the following advantages:

1) Real time measurements can be made of power savings, and thus an interruption to an electricity supply is not required;

2) A measurement system allows a user to configure a power conditioner remotely, or to analyse power savings of a plurality of power conditioners; and

3) Power savings may also be demonstrated without the power conditioner in order to demonstrate power savings using an assumed voltage output from the power conditioner.

The above description of various embodiments of the present invention is provided for purposes of description to one of ordinary skill in the related art. It is not intended to be exhaustive or to limit the invention to a single disclosed embodiment. As mentioned above, numerous alternatives and variations to the present invention will be apparent to those skilled in the art of the above teaching. Accordingly, while some alternative embodiments have been discussed specifically, other embodiments will be apparent or relatively easily developed by those of ordinary skill in the art. Accordingly, this patent specification is intended to embrace all alternatives, modifications and variations of the present invention that have been discussed herein, and other embodiments that fall within the spirit and scope of the above described invention.

1. A method of measuring electrical power including the steps of:
measuring a first electrical input variable at an input to a power conditioner connected to an electricity supply;
measuring one or more electrical output variables at an output of the power conditioner;
calculating a second electrical input variable at the input to the power conditioner according to the one or more electrical output variables measured at the output and the first electrical input variable measured at the input;
calculating an estimated power according to the measured first electrical input variable and the calculated second electrical input variable; and
sending the estimated power via a data interface.

2. The method of claim 1 wherein the first electrical input variable is an input voltage and the second electrical input variable is an estimated input current.

3. The method of claim 1 wherein the first electrical variable is an input current and the second electrical variable is an estimated input voltage.

4. The method of claim 1 wherein the one or more electrical output variables measured at the output includes one or more of an output voltage, an output current, and an actual power.

5. The method of claim 4 wherein the actual power is one or more of an apparent output power and a real output power.

6. The method of claim 1 wherein the estimated power is one or more of an estimated apparent power and an estimated real power.

7. The method of claim 4 including calculating a power difference between the estimated power and the actual power, and sending the power difference via the data interface.

8. The method of claim 7 wherein a level of power savings is calculated from the power difference.

9. The method of claim 1 including calculating an output voltage according to a desired level of savings set by a user, and setting the output voltage of the power conditioner according to the calculated output voltage.

10. The method of claim 1 including calculating a power loss of the power conditioner.

11. The method of claim 10 wherein the power loss is an apparent power loss.

12. The method of claim 10 wherein the power loss is a real power loss.

13. A measurement system, the measurement system including:
a processor and a memory coupled to the processor, the memory including computer readable program code components configured to cause the processor to:
measure a first electrical input variable at an input to a power conditioner connected to an electricity supply;
measure one or more electrical output variables at an output of the power conditioner;
calculate a second electrical input variable at the input to the power conditioner according to the one or more electrical output variables measured at the output and the first electrical input variable measured at the input;
calculate an estimated power according to the measured first electrical input variable and the calculated second electrical input variable; and
send the estimated power via a data interface.

14. The system of claim 13 wherein the first electrical input variable is an input voltage and the second electrical input variable is an estimated input current.

15. The system of claim 13 wherein the first electrical variable is an input current and the second electrical variable is an estimated input voltage.

16. The system of claim 13 wherein the one or more electrical output variables measured at the output includes one or more of an output voltage, an output current, and an actual power.

17. The system of claim 16 wherein the actual power is one or more of an apparent output power and a real output power.

18. The system of claim 13 wherein the estimated power is one or more of an estimated apparent power and an estimated real power.

19. The system of claim 16 wherein the computer readable program code components are configured to cause the processor to calculate a power difference between the estimated power and the actual power, and sending the power difference via the data interface.

20. The system of claim 13 wherein the computer readable program code components are configured to cause the processor to calculate an output voltage according to a desired level of savings set by a user, and setting the output voltage of the power conditioner according to the calculated output voltage.
